(19) United States
(12) Patent Application Publication
(10) Pub. No.: US 2013/0307524 A1
(43) Pub. Date: Nov. 21, 2013

(54) INFERRING THE PERIODICITY OF DISCRETE SIGNALS

(71) Applicant: Ramot at Tel-Aviv University Ltd., (US)

(72) Inventors: Yuval Shavitt, RaAnana (IL); Udi Weinsberg, Ashdod (IL); Oded Argon, Tel-Aviv (IL)

(73) Assignee: Ramot at Tel-Aviv University Ltd., Tel-Aviv (IL)

(21) Appl. No.: 13/875,486

(22) Filed: May 2, 2013

Related U.S. Application Data
(60) Provisional application No. 61/641,423, filed on May 2, 2012.

(51) Int. Cl. G01R 23/02

(52) U.S. Cl. CPC G01R 23/02
USPC 324/76.39

(57) ABSTRACT

A method for testing a signal comprises obtaining a signal, determining whether the signal has at least one period, measuring that period and providing the measurement as output. A power spectral density estimation can be used for signals having a single period, and an autocorrelation function with slicing can be used in an iterative procedure for finding multiple periods within signals.

### RELATED APPLICATION

This application claims the benefit of priority under 35 USC 119(e) of U.S. Provisional Patent Application No. 61/641,423 filed May 2, 2012, the contents of which are incorporated herein by reference in their entirety.

### FIELD AND BACKGROUND OF THE INVENTION

The present invention, in some embodiments thereof, relates to inferring periodicity of discrete signals, in particular but not exclusively to looking for behavioral patterns in network signaling, such as Internet signaling.

Human behavior often follows periodic patterns as a result of daily work, leisure and rest habits, weekends and even yearly holidays. These patterns directly affect the way Internet resources are consumed, e.g., creating peak bandwidth hours, availability of hosts and resources, and mobility patterns. As a result, network operators often engineer their networks to accommodate these periodic changes in various ways.

Not just human initiated but also automated software has behavior that often follows periodic patterns.

Excessive traffic during peak hours may result in congestion on routers or servers, impacting user satisfaction. Network engineers commonly overcome this using two simultaneous links: a low cost link with sufficient capacity for most of the day, and a more expensive spill-over link with a usage based cost. Alternatively, it is now becoming increasingly common to perform traffic shaping during peak hours. Another example is the availability of end-hosts and their IP addresses assignment, the first is mostly determined by human habits, while the latter is often an engineered process of the serving ISPs. Both have implications for peer-to-peer applications, online fraud detection, and on content distribution networks, that need to know which host is available and via which IP address it can be reached.

Although it is important to detect these periodic patterns and understand their effect on network resources, most patterns are not exposed by network operators, or even deliberately engineered. Measurement efforts that attempt to discover and analyze the patterns perform repeated measurements using various techniques, and post-process them for extracting insightful information. Such measurements can be viewed as a sampling process of the actual behavior. However, the inference of periodicity in the samples is a non-trivial task, mainly due to the intrinsic measurement noise.

Simple signal analysis methods, such as FFT (Fast Fourier Transform) or signal autocorrelation can find the periodicity of a signal, but do not always work well with the type of noise one see in many process such as the ones measured in the Internet.

More importantly, traditional signal processing techniques cannot find multiple periodic patterns that exist in a signal, which are important to many applications, e.g., if one measures some Internet activity the pattern may contain two periods: one caused by the user of the monitored machine, say which has a daily pattern, and one caused by malware, which has penetrated the machine, and which can have a different period (say every hour). In particular, the ability to identify the presence of malware from its effects by monitoring from remote locations is a powerful part of network management and a powerful weapon in the fight against malware.

Monitoring networks and behavioral patterns is a key aspect of network management and has been addressed by several groups. One group measured two OC-3 trunks for 7 days and observed a daily period with varying duty-cycles in the volume of bytes, number of flows, number of packets, TCP traffic, etc. Another group studied datasets of a cellular network operator, exhibiting a clear daily load periodic pattern. Yet another group studied the self-similarity of Ethernet traffic, and showed daily cycles in some of their datasets.

A major challenge that does not exist in related frequency inference techniques is that one cannot assume that the signal is indeed periodic. Current methods fail to first determine whether periodic patterns in fact exist, but rather assume that they do, and on this basis proceed to infer their period length.

### SUMMARY OF THE INVENTION

The present embodiments provide a method and apparatus for analyzing behavioral patterns in discrete data, such as the ones taken from measuring of observing Internet activities, to find whether they are periodic. In case of a positive answer the method finds the length of the strongest periodic intervals, e.g., one can find that user Internet access behavior exhibits daily as well as weekly patterns.

The present embodiments consider measurements and logs of such behaviors as discrete signals in time, and analyze the signals in order to find whether they exhibit periodic behavior.

According to an aspect of some embodiments of the present invention there is provided a method for testing a signal comprising:

Obtaining the signal;

Determining whether the signal has at least one period;

Measuring the period; and

Outputting the period.

In an embodiment, if a single period is found then a power spectral density method is used as the most efficient way to find the period. If multiple periods are found, then an embodiment obtains an autocorrelation of the signal, slicing the autocorrelation into slices, wherein the determining whether the signal has at least one period comprising for each slice finding peaks and lags, and wherein the measuring the signal comprises setting a period as a longest one of the lags.

An embodiment comprises iteratively coarsening the slices to find further periods in the signal.

An embodiment may stop the iterative coarsening when all determined periods are contained within a single slice.

In an embodiment, when the determining whether the signal has at least one period comprises determining that the signal has only one period, using a power spectral density to determine the frequency of the only one period.

In an embodiment, the outputting the period comprises outputting a list of all periods found in the obtained signal, and providing a confidence value for each period in the list.

An embodiment may comprise calculating the confidence value by dividing a number of lags found by a number of lags expected for the current period.

An embodiment may comprise finding successively longer periods in the obtained signal by iteratively relaxing a time-domain autocorrelation function.

In an embodiment, the finding successively longer periods at least partly comprises finding peak levels in the autocorrelation function, peak levels of different amplitude being assigned to different periods and peak levels of a same amplitude being assigned to a same period.

In an embodiment, the obtaining a signal further comprises shaping the signal to capture a periodic change therein.

In an embodiment, the capturing comprises one member of the group comprising:
a) apply a start value and repeatedly negate the value upon changes in the signal;
b) for a signal having a range, dissecting the range into two range parts and assigning each range part a value from {“1”, “−1”}; and
c) obtaining a number of packets per predetermined time period.

In an embodiment, the output at least one period is used to obtain at least one member of the group consisting of: an availability of end-hosts on a network, a usage of inter-network links on a network for balancing load and cost of transit, optimal peak hour traffic shaping, alternation of allocated IP addresses, malicious host identification, network forensic analysis, and tracking infected hosts over time using their IP addresses.

According to a second aspect of the present invention there is provided apparatus for testing a signal comprising:

an input for obtaining the signal;

a period detector for determining whether the signal has at least one period;

a period measurement unit associated with the period detector configured to measure the period; and

an output for outputting the measured period.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. The data processor may include a volatile memory for storing instructions and/or data and/or a non-volatile storage, for example, a magnetic hard-disk, flash memory and/or removable media, for storing instructions and/or data. A network connection may be provided and a display and/or a user input device such as a keyboard or mouse may be available as necessary.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1A is a flow diagram showing a generalized embodiment of the present invention;

FIG. 1B is a simplified diagram showing a high level view of the autocorrelation method for use when multiple periods have been detected in the incoming signal, according to an embodiment of the present invention;

FIG. 1C is a simplified schematic block diagram illustrating apparatus for carrying out the method of FIGS. 1A and 1B;

FIGS. 1D-1F show examples of a signal given phase noise, sampling noise and multiple periods;

FIGS. 2A-2H are schematic diagrams showing power spectral density (PSD) functions of a signal comprising a simulated signal with a single period (A-D), two periods (E-F), phase noise (G) and sampling noise (H);

FIGS. 3A-3H are schematic diagrams showing autocorrelation functions (ACF) of a signal comprising a simulated signal with a single period (A-D), two periods (E-F), phase noise (G) and sampling noise (H);

FIGS. 4A-4C are examples of MPE execution phases, detecting three different periods;

FIGS. 5A-5F are schematic graphs illustrating simulation results of increasing phase noise, sampling noise and number of sampled periods;

FIGS. 6A-6D show simulation results of MPE accuracy and confidence in the face of phase noise and sampling noise with four periods;

FIGS. 7A-7C show simulation results o MPE accuracy and confidence of a period ratio using a two-period signal;

FIGS. 8A-8D show cumulative distribution of availability periods; and

FIGS. 9A-9D illustrate cumulative distribution of IP alternation periods.

### DESCRIPTION OF SPECIFIC EMBODIMENTS OF THE INVENTION

The present invention, in some embodiments thereof, relates to identification of periodicity in a signal and the subsequent identification of multiple layers of periodicity if present.

As discussed, the prior art assumes that periodicity is present and attempts to determine its period. The present embodiments first determine whether periodicity is present and only then do they attempt to extract one or more periods from the data.

The method was tested both on real data and simulated data and was shown to be both resilient to noise and to be able to find multiple periods. In particular, the methods of the present embodiments may be resilient to the following noises on a bipolar square signal: phase noise, sampling noise, and a non-symmetric duty cycle.

In order to infer these periodicities the data may be treated as a signal and may serve as input to the presently discussed Multiple Period Estimation (MPE) algorithm. The output of the algorithm is a list of periods found in the input signal with a confidence value for each period.

Many network events exhibit a periodic pattern. Such applies to communication networks including telecommunication networks, cellular networks and the Internet.

Such events include the availability of end-hosts, usage of inter-network links for balancing load and cost of transit, traffic shaping during peak hours, etc. Internet measurement efforts that aim at capturing such events perform repeated probing, which is susceptible to measurement noise, making periodicity inference of the sampled processes a non trivial task. The present embodiments include a method for assessing the periodicity of network events and inferring their periodic patterns. An existing method uses Power Spectral Density analysis for inferring a single dominant period that exists in a signal that represents the sampling process. This method is robust to noise, but is only useful for single-period processes. The method of the present embodiments provides a further method for detecting single or multiple periods of a single process, using iterative relaxation of a time-domain autocorrelation function. We evaluate these methods using extensive simulations, and show their applicability on real Internet measurements used for on-line frauds and botnets detection.

The present embodiments provide methods for detecting periodic patterns, for example in Internet measurement data. We first convert the measurement data into a canonical signal, and then apply period inference methods for extracting the periodic patterns that comprise it. We use a frequency-domain method for robustly inferring a single dominant period, and an iterative, but more time-consuming, time-domain method for extracting all periods that comprise the signal.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

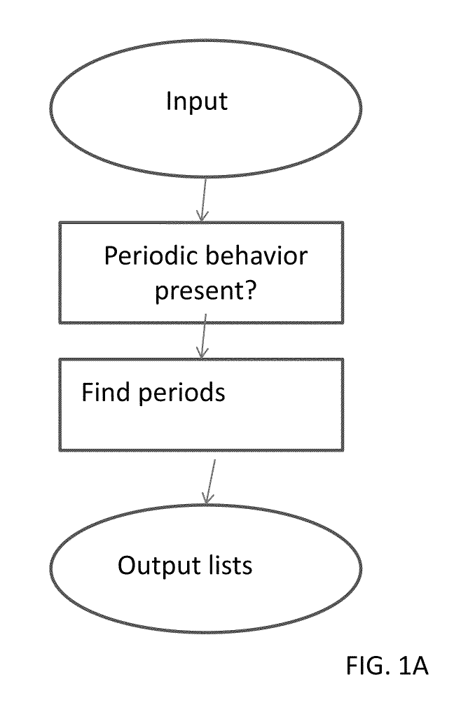

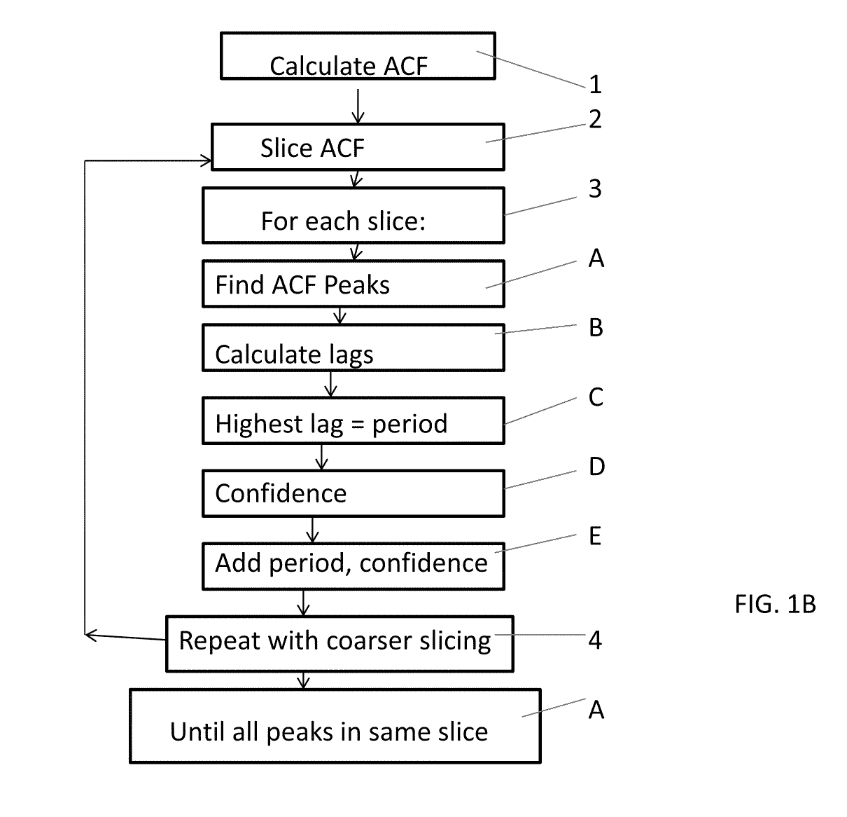

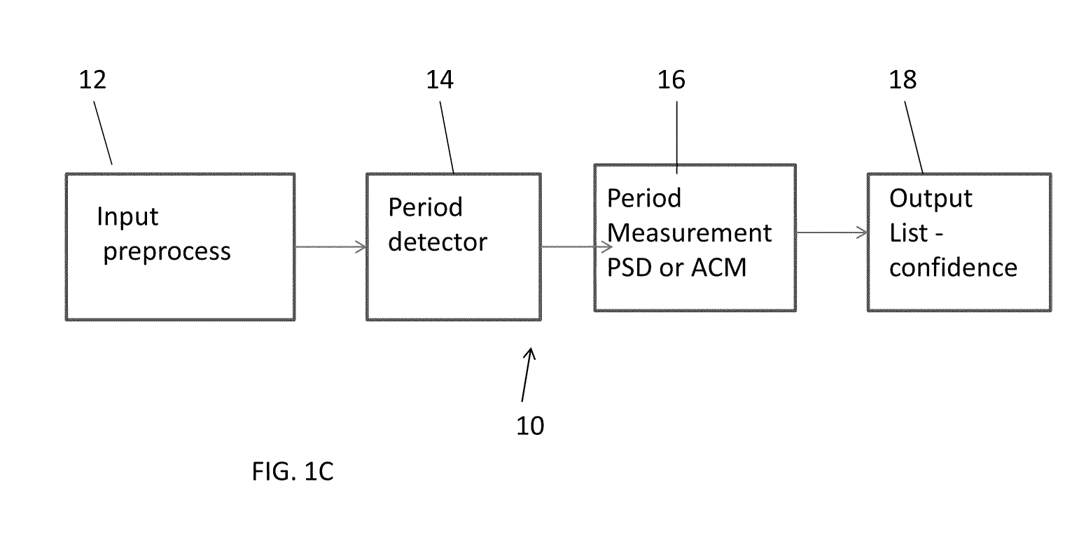

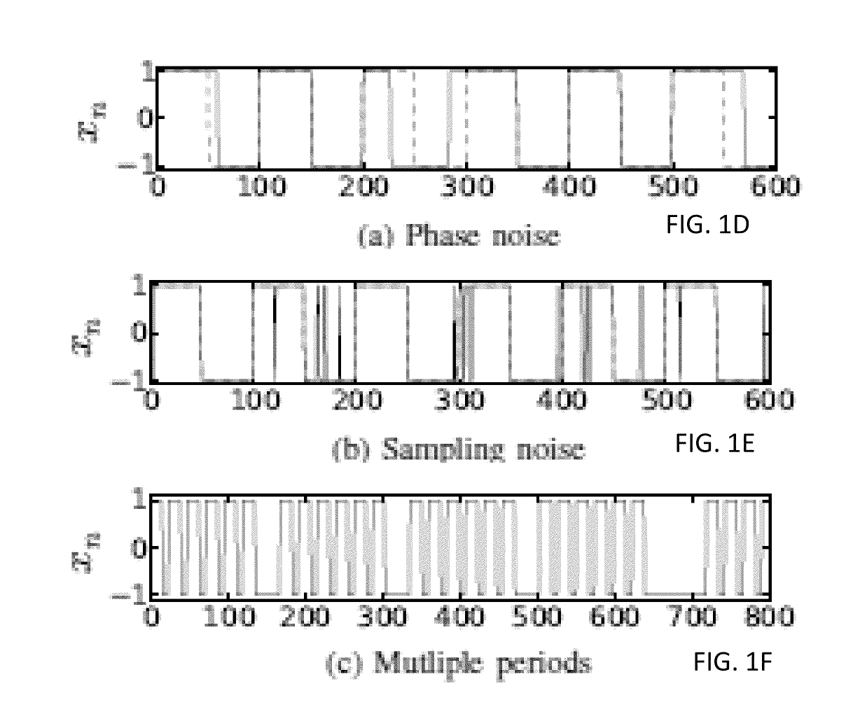

Referring now to the drawings, reference is now made to FIG. 1A which is a simplified flow chart showing a method for testing a signal in order to find out if it contains periodic behavior and if so, what measurements apply to those periods.

As shown in FIG. 1A, the initial stage involves obtaining the signal. As explained below the obtained signal may be usable directly or may need processing before it can be used. Then the signal is examined to determine whether or not it contains periodic behavior of any sort. Once periodic behavior is determined to be present then the signal is analyzed to determine the period or periods present. Finally an output is provided of the obtained periods and optionally any additional data such as certainty levels for the individual periods. As discussed below, if only a single period is found to be present then a power spectral density can be used to find the period. If multiple periods are present then the autocorrelation method is used.

FIG. 1B illustrates in greater detail the time domain autocorrelation method according to the present embodiments. In general, the autocorrelation method comprises obtaining an autocorrelation of the signal, slicing the autocorrelation into slices, for each slice finding peaks and lags, and setting a period as a longest one of the lags. The process is repeated as the autocorrelation is successively relaxed, and a stopping condition for the iteration may be set when all the periods appear in the same slice.

The output may be a list of all periods found in the signal, and these may be provided with a confidence value for each period. As will be discussed in greater detail below, calculating the confidence value may involve dividing a number of lags found by a number of lags expected for the current period.

The stages in the algorithm are as follows:
1. Calculate a normalized Auto Correlation function (ACF) of the signal.
2. Divide the Y axis of the ACF into slices.
3. For each slice:
   a. Find ACF peaks.
   b. Calculate lags between consecutive peaks.
   c. The highest lag represents a period in the signal.
   d. Calculate a confidence value for the period.
   e. Add the period and confidence to the list of found periods.
4. Go to step 2 with a coarser slicing.
   a. Stop if all the peaks are in the same slice.

The algorithm may find that there is no periodic activity, or that there is one period or that there are multiple periods.

In the autocorrelation method, peak levels of different amplitudes may be found in the autocorrelation function. Peak levels of different amplitude may then be assigned to different periods, whereas peak levels sharing a common amplitude may assigned to a common period.

The input signal may need to be preprocessed, including being shaped and/or cleaned to capture a periodic change therein. As will be discussed in greater detail below, ways of processing the input for period detection may include the following:
a) apply a start value and repeatedly negate the value whenever the signal changes, or changes by more than a threshold amount;
b) for a signal with a range, dissecting the range into two range parts and assigning each range part a value from {“1”, “−1”}; and
c) for a packet-type network, obtaining the number of packets per predetermined time period.

The period information can be used for a number of applications. Examples include an availability of end-hosts on a network, a usage of inter-network links on a network for balancing load and cost of transit, optimal peak hour traffic shaping, alternation of allocated IP addresses, malicious host identification, network forensic analysis, and tracking infected hosts over time using their IP addresses;

an input 12 obtains the signal, and carries out any necessary preprocessing, including sampling, shaping and noise reduction; and

a period detector 14 determines whether the signal has periodic behavior. As discussed above, this is a point which is missing in the prior art. Although the prior art can look for the strongest periodic behavior, it does not initially check that there is any period present in the data, so that the final output could be meaningless. Furthermore the prior art, in tending to look for the strongest period, is unable to deal effectively with data having multiple periods.

A period measurement unit 16 measures the period or periods in the data. As discussed above, if there is a single period then the PSD method is used as the most efficient method to detect the period. Otherwise the autocorrelation method is used.

Output 18 provides a list of the determined periods, optionally together with confidence levels.

Next we show an embodiment of the algorithm in greater detail. Each step is to be considered and the algorithm above with each step or a group of steps replaced by the corresponding embodiment from below is also part of this patent.
1. Calculate a normalized Auto Correlation function (ACF) of the signal
   a. The auto-correlation function, Rn, is of the form:

$$\begin{matrix}{\hat{R}}_{n} = \frac{{\sum }_{m = 1}^{N} f ( {x}_{m} , {x}_{m - n} )}{N - n} & n = 1 , 2 , … , N - 1 \\ {R}_{n} = \frac{{\hat{R}}_{n}}{{\hat{R}}_{0}} & n = 1 , 2 , … , N - 1\end{matrix}$$

where f(x,y) is a weight function used to quantify the match between the values of x,y.
   i. For example: the weight function f(x,y) can be simply f(x,y)=x*y for a binary signal of [−1,1] which will result in a weight of 1 if the values are the same or −1 if the values are different.
2. Divide the Y axis of the ACF into fine grained slices.
   a. For example: start with 10 even slices.
3. For each slice:
   a. Find peaks of the ACF in the current slice.
      i. A threshold of minimum peaks should be set as a filter.
      ii. A peak is a local maxima point where the peak point is higher than the surrounding points. A threshold is used for the surrounding to look at to set a point as a peak.
   b. Calculate all the lags between consecutive peaks.
   c. Calculate a histogram of the lag values using bins.
      i. The value of the highest bin represents a period in the signal if that bin is above some probability threshold in the histogram.
         1. The period is calculated using the bin value and the sampling frequency of the input signal as: P=(Bin*fₛ¹)
   d. A confidence value is calculated by dividing the number of lags found in the bin by the number of lags we expect to find for the current period.
   e. Add the period and confidence to the list.
      i. If the period is already in the list, keep the highest confidence value.
4. Repeat the process from (2) with a rougher slicing of the Y axis.
   a. Stop if all the calculated peaks are in one slice.

For 1(a) above, three types of input signal are considered:
1. A bipolar signal of [−1,1] values.
   a. There are several ways to generate a bipolar signal from real measurements or real data.
      First, in the trivial case where the measured variable has only two possible values, one value is mapped to “1” and the other to “−1”. Second, if the measured variable has multiple possible discrete values we have two options depending on our interest. One is to measure a change in the value. In this case, we arbitrarily start with some value, say “1”, and every time we see a change in the variable we negate the value. This allows capture of periodicity in the dynamics of the variable changes. Another option when multiple values are possible, is to dissect the value range into two and assign each range a value from {“1”, “−1”}. As a result of the above we are left with a signal xₘ that takes the value 1 or −1.
   b. For this signal a weight function f(x,y)=x*y is best suited. The same value is treated as one and a different value is treated as minus one.
2. A general signal with discrete values representing discrete states. For example, consider the case of wanting to find periodicity in the values and not just value changes, as discussed for the bipolar signal.
   a. Each unique value in the input signal may be assigned an arbitrary unique value (e.g. 1,2, etc).
   b. For this signal a suitable weight function, f(x,y), can be a function that outputs one if x equals y and minus one if x does not equal one. Thus, we get the same autocorrelation result of the bipolar signal.
3. A general signal with quantitative values, for example, the amount of packets received every second in some system.
   a. Here we use can use raw measurement data for the analysis.
   b. There is no one recommended option for the weight function f(x,y) as it strongly depends on the sample data and values but the function may be chosen such that matching values output a one, and non-matching values output minus one. A value in between one and minus one will be the output to note the distance between the values.
      i. For example, one might consider a difference in quantity of 10 messages a match but a higher difference is not a match. Thus, the weight function can output one for the exact same quantity, one minus some distance function if the difference is up to 10, and minus one otherwise.

Note that while the most striking feature of the algorithm is its ability to identify multiple periodicities in the signal, it is also good at cleaning noise in a single period in a signal.

In the following, we present the concept of periodicity in Internet measurement data, pointing out the difficulties of multiple period inference and noise factors. Next, the above-referred to Power Spectral Density estimation method is used on a signal constructed from the measurements, and it is shown to be useful specifically for detecting a single dominant period. The time-domain iterative method of the present embodiments is then presented that is capable of robustly inferring all periods. Extensive simulation for studying the operational boundaries of these methods in the domain of network measurements data is demonstrated; including evaluating the applicability of the methods on real-world data; and showing their success in detecting multiple periods that align with human behavior.

II. Signal Construction

The first phase of the above consideration of the input signal is to construct a signal that represents the actual process being investigated. Consider a sequence S of N discrete samples, S={s₁, . . . , s_{N}}, where sᵢ ∈ C and C is a set of possible values. In this paper we focus on two types of processes:

1) Dual-state processes, namely ÅCÅ=2. Alternatively, processes may have multiple values which are classified into two states.

2) A processes with multiple states, but we are interested in the point where the state changes and model this with two values that alternate at each state change.

Formally, the input samples S are converted to a canonical signal xn, {x1, . . . , xN|xi=±1}. For dual-state processes, C contains two possible values, C={c1, c2}, making construction of xn straightforward:

$${x}_{n} = \{ \begin{matrix}1 & {s}_{n} = {c}_{1} \\ - 1 & {s}_{n} = {c}_{2}\end{matrix} \qquad ( 1 )$$

For the alternating process let C={c1, . . . , cK} where K is the number of possible sample values. The signal xₙ is represented using the same canonical notation, so that it keeps its value while the probe process contiguously samples the same value, and inverses when the sample results in a different value:

$${x}_{n} = \{ \begin{matrix}1 & n = 1 \\ {x}_{n - 1} & if {s}_{n - 1} = {s}_{n} \\ - {x}_{n - 1} & otherwise ,\end{matrix} \qquad ( 2 )$$

For the alternating process let C={c1, . . . , cK} where K is the number of possible sample values. The signal xₙ is represented using the same canonical notation, so that it keeps its value while the probe process contiguously samples the same value and inverses when the sample results in a different value:

$${x}_{n} = \{ \begin{matrix}1 & n = 1 \\ {x}_{n - 1} & if {s}_{n - 1} = {s}_{n} \\ - {x}_{n - 1} & otherwise ,\end{matrix} \qquad ( 2 )$$

Reference is now made to FIGS. 1D to 1F, which illustrate examples of xₙ given phase noise, sampling noise and multiple periods.

A. Number of Periods

The simplest classification of a process can be either periodic, e.g., with daily or weekly period, or non-periodic. However, some processes may exhibit multiple periods. For example, consider a cellphone tower that is next to a large corporate office. During workdays the amount of traffic it carries exhibits daily periods including peak hours, while during weekends the traffic goes almost to zero. Although both patterns exist simultaneously, the weekly pattern is actually an interference in the daily period, because it creates imperfections in the daily pattern. The weekly pattern is perfect, unless the study is sufficiently long that it manages to include yearly patterns that harm some instances of the weekly pattern, due to yearly holidays for example.

FIG. 1F depicts such a simulated signal, exhibiting a daily pattern (with non-symmetric duty-cycle), a weekly pattern, and a monthly pattern. Notice that the weekly patterns are observed due to a disturbance in the daily pattern (1 in every 7 days is different), and similarly, the monthly patterns are simply imperfections in the weekly pattern.

When multiple periods exist, the expected outcome is highly subjective. One may argue that the longest period (the monthly in the above example) is the most significant, because its periodic pattern is more perfect than the others. More commonly, the shortest period (the daily) may be considered more important, since it is the most dominant (contains the highest amount of energy, in signal processing jargon) and already includes other periods (the weekly and monthly are harmonics of the daily period). Finally, one may want to infer all of the existing periods.

In either case, in order to be able to distinguish between periods, there must be a clear difference between them. For example, a yearly pattern with three days off in every year will be almost impossible to separate from a weekly pattern with two days off in every week.

We propose here two methods: one for detecting the highest occurring period using frequency domain analysis; and a more complicated time-domain analysis for inferring all periods.

B. Alternations and Duty-Cycle

Two fundamental parameters of a square signal are its duty-cycle and number of cycles or alternations per period. A simple signal has a single alternation, meaning it changes states only once per period. The duty-cycle of such a signal is the percent of time that the signal is in one state. A symmetric duty-cycle means that in each period the first half the signal is one state and the other half it is in the second state.

The sampled process may have a non-symmetric duty-cycle, meaning that the change between states may occur anywhere within the period. This is common in human related behavioral patterns, for example, peak hours exhibit a daily pattern, but take at most 6 hours, making a duty-cycle of roughly 0.25. Since we seek to find the periodicity of these processes, our methods make no assumption on the duty-cycle.

A perfect single-period signal (without noise) has a single alternation per period, i.e., xn has a single zero-crossing per period. When noise exists, xₙ may have more than one zero-crossing per period; however, this should be filtered out by the inference methods. In signals with multiple periods, each period except for the shortest is bound to have more than a single alternation. For example, FIG. 1E is comprised of two periods, a short period, which has a single alternation and a duty cycle of roughly 66%, and a long period that has multiple alternations and a completely non-symmetric duty-cycle: for each 6 repeats of the fast periodic pattern, it has a short duration of the fixed state “−1”.

C. Noise Models

We include in our model two types of noise that are a common result of discrete sampling. The first type is when the sampling process exhibits a jitter, i.e., it misses the exact time of a change that occurred in the sampled process. This is common due to not frequent enough sampling, and causes xₙ to have a delayed response to the real change. Since this delayed response is not likely to be consistent, xₙ will exhibit variability in the period lengths. FIG. 1D depicts such a signal, having cycles with wider or narrower periods than the real one (dashed lines).

We refer to this type of noise as phase noise, where the skewing of the phase in the resulting signal depends on the distance between the sampling and the actual event. Given that fₛ is the sampling rate, assumed to be at least at Nyquist rate, i.e., twice the sampled frequency, the error in the period inference is at most ±1/fₛ; +1/fₓ occurs when a sample is immediately after the real change and the following sample is right before the real change, thus missing until the next sample, and −1/fₛ occurs when a sample is right before the real change, thus missing it until the next sample, and the sample afterwards is immediately after the following change. Phase noise can also be the result of jitter in the process itself. For example, the exact peak-hour time that causes a link to become congested is not consistent. Furthermore, the sampling process itself is often not accurate, and may exhibit different intervals between samples. The only important aspect to maintain is that the sample process is performed at least at the Nyquist frequency, i.e., twice the frequency of the process, so that it does not misses actual changes.

The second type of noise occurs due to errors in the sampling, e.g., a sampling process of the load on a link incorrectly reported that the link is congested even though it was not. We refer to this type of noise as sampling noise.

The result of sampling noise on xₙ differs depending on the sampled process. In dual-state processes, xₙ will have wrong values for each wrong sample. We expect that only a few contiguous samples will be incorrect, thus the effect on xₙ is local and, given a sufficiently high fs, relatively short. FIG. 1E provides an example of sampling noise (3% of the samples are wrong, up to two contiguous errors).

On the other hand, when sampling alternating processes, contiguous sampling errors may have a more global effect. If the incorrect sample resulted in a single value, then the result is a local noise in xₙ, since right after the incorrect samples, the correct sample is made, and xₙ returns to the correct form. However, if there were two (or any even number of) errors that resulted in two different incorrect values, then once returning to the correct value, xₙ is inverted relative to what it would be without the errors. Contiguous sampling of two different and incorrect values should be a very rare case, and we assume that in the case of alternating signals, special care is taken to assure the accuracy of the sampling process, so that this case is avoided.

Notice that sampling noise is a special form of the common amplitude noise. When the sampling process experiences an amplitude noise that is high enough for incorrect classification of the sampled value, it translates into a sampling noise according to our definition.

IV. Period Inference Methods

In this section we present two methods for inferring the periodicity of the sampled signal. The first method is the known method using Power Spectral Density (PSD) estimation in the frequency domain for finding the most energetic period. We then present a further method, which we call Multiple Period Estimation (MPE), that iteratively builds histograms of the intervals between peaks observed in the Autocorrelation Function (ACF).

PSD returns the inferred period, P̂, and a confidence value ξ, that quantifies the probability that the signal is indeed periodic with the inferred period. In case of MPE, multiple pairs (P̂, ξ) are returned, one for each inferred period.

We note that intuitively, simple statistical inference methods can be applied. For example, it is possible to create a histogram of the times between alternations in xₙ, and consider the peaks as representing half of the period. Such a method, however, assumes a duty-cycle of 0.5, and moreover, it does not consider the order of events and assumes that they are interleaved. Furthermore, averaging and smoothing is required for the method to handle noise well. Thus, we use techniques that are more complicated, but which have good properties for the present problem domain.

A. Method A: Power Spectral Density

One of the basic signal processing tasks is to perform a Power Spectral Density (PSD) estimation of the signal, i.e., estimate the power that each frequency holds (power spectrum). The basis for spectral density estimation of a signal xₙ is the Discrete Fourier Transform (DFT) that converts the time-domain signal into the frequency domain.

Before applying DFT, we normalize the signal in order to remove any DC (corresponding to zero frequency) artifacts. This is particularly important for signals with non-symmetric duty-cycle, that have a non-zero mean. Thus, let μ denote the mean value of xₙ, i.e., μ= [symbol] , we compute the normalized signal Xn using:

X̂ₙ=xₙ₊₁−μ, n=0, . . . , N−1 (3)

Notice we also shifted the signal to make it zero-based, allowing simpler DFT computation. The DFT off is then computed using:

$$Xk = \begin{matrix}\begin{matrix}N - 1 \\ \end{matrix} \\ n = 0\end{matrix} x \hat{} ne - 2 π kni \text{/} N \\ k = 0 , 1 , … , N - 1 \qquad ( 4 )$$

The power of each frequency is computed simply using the squared amplitude of each complex component in the DFT. For computing the PSD, we apply Welch's average method, a method that uses segmentation, windowing and averaging for improving the statistical properties of the resulting spectral estimates. Using PSD, it is straightforward to compute the fundamental frequency of the signal, which is the one that holds the most energy. We use it for inferring the period (inverse of the frequency) of the signal by computing:

$$\hat{P} = {( arg {max}_{k} [ \vert {X}_{k} \vert ] \cdot \frac{{f}_{x}}{N} )}^{- 1} \qquad ( 5 )$$

PSD provides all the frequencies that comprise the signal, including their harmonics (multiplications of the fundamental frequencies). Since we do not consider harmonics as useful periods, theoretically, extracting the significant periods can be achieved by iteratively selecting the highest peak with a frequency smaller than the last detected peak (higher frequencies are a result of harmonics or noise). However, when facing noise or when multiple periods exist in the signal, secondary peaks have energy levels that are almost indistinguishable from peaks that are the result of noise and side-lobes.

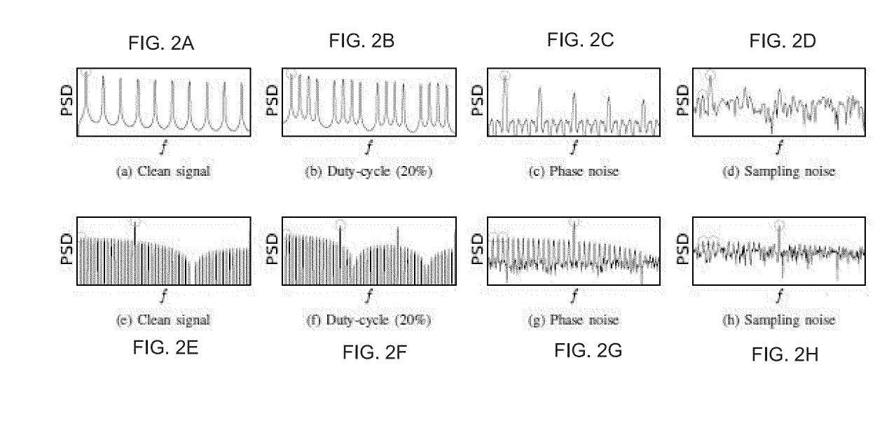

Reference is now made to FIG. 2, which plots the PSD of a signal with a single period (top plots, 100 samples per cycle, 15 cycles) and a signal with two periods (bottom plots, zoomed, second period is 10 cycles of the first period, with added 100 samples of −1 between each cycle). For each type of signal, the figure shows it with no noise, with added phase noise (10% of alternations, jitter of at most 2 samples), with added sampling noise (10% of the samples, at most 2 incorrect samples) and with non-symmetric duty-cycle (20%).

All plots exhibit a clear peak, corresponding to the fundamental frequency of the signal. This can easily be inferred, regardless whether noise exists. FIG. 2c shows that phase noise already creates a significant number of secondary peaks, whereas FIG. 2d shows that sampling noise causes even more noticeable peaks, resulting in a false detection of a second frequency.

FIG. 2e shows that using two periods and no noise the two periods are correctly detected, and FIG. 2f shows robustness to duty-cycle, which is a result of the normalization. However, when noise exists (FIG. 2g and FIG. 2h), the second period is not correctly detected, since there are peaks that are higher than the one matching the correct period. Furthermore, the peaks are not aligned as clean harmonics (not exact multiplications of the fundamental frequency), resulting in an inaccurate frequency inference and a very complex harmonic filtering strategy.

Given the above, we use PSD for the detection of a single period, a task that suits many monitoring applications. Since it is easily and efficiently implemented (using Fast Fourier Transform), this method is quite useful and, as we show in Sec. V, is very robust to noise.

Computing the period confidence, ξ is achieved by summing the energy of the inferred frequency and its harmonics (since the energy of the frequency is divided amongst all harmonics), and normalizing it using the energy of the complete signal. Assume that k is the index of the peak that resulted in period P̂, we denote by M the set of harmonics of P̂, i.e.,

$$\{ n \cdot \hat{P} \} , n = 1 … ⌊ \frac{N}{k} ⌋ .$$

We then compute using:

$$ξ = \frac{{\sum }_{m ∈ M} {\vert {X}_{m} \vert}^{2}}{{\sum }_{m} {\vert {X}_{m} \vert}^{2}} \qquad ( 6 )$$

When multiple peaks are detected, it can either be a result of noise or existence of multiple periods. In this case we perform the method described next, which is capable of extracting all periods that comprise the signal.

B. Method B: Multiple Period Estimation

Similar to DFT, the autocorrelation function (ACF) is an averaging method, only it operates in the time domain. ACF measures how well a signal is correlated with a shifted version of itself. More formally, the normalized ACF of a discrete signal xn can be defined as:

$${R}_{n} = \frac{{\sum }_{m = 1}^{N} {x}_{m} {x}_{m - n}}{N - n} , n = 0 … N - 1 \qquad ( 7 )$$

where Rn is the normalized ACF of lag n. Since we only use this form of normalized ACF herein, we refer to it simply using the term ACF. For periodic signals, the ACF is periodic with the same period.

Notice that the ACF results in the same weight for different shifts of the signal, however, high shifts capture only a small portion of the signal, whereas low shifts capture a significant part of the signal, and should have more influence. Thus, we assume that the signals are long enough so that sufficiently far lags do not affect the result. We evaluate the effect of the signal length on the resulting period in Sec. V hereinbelow.

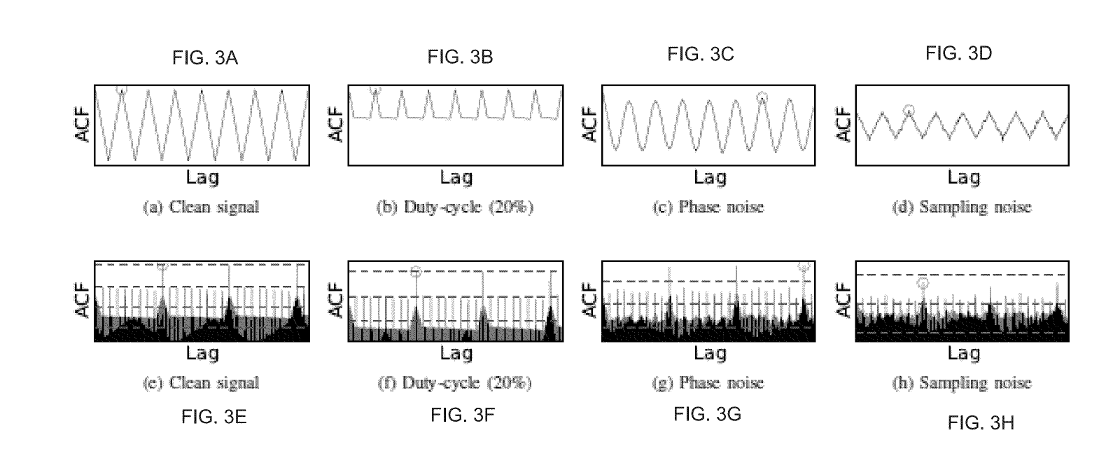

A key strength of ACF that makes it useful for finding repeating patterns, is that it smoothes both sampling and phase noise, since these types of noise affect only small sections of the signal. FIG. 3 plots the ACFs of a signal with a single period (upper plots) and a signal with three periods (lower plots), each with different types of noise and duty-cycle. In the single period plots, the periodic pattern is clearly visible. FIG. 3c shows that phase noise causes the ACF to lose its linearity, while sampling noise, depicted in FIG. 3d lowers the peak value. The non-symmetric 20% duty-cycle in FIG. 3b cuts the lower parts of the ACF, since there is no lag that results in an inverted-phase, which causes the negative peaks in a 50% duty-cycle signal. However, the periodic pattern in all variations is still clear.

ACF by itself and with normalization improvements is commonly used for inferring periodicity, e.g., inferring the pitch of musical and human speech signals, however it is still known to be unreliable. For example, consider the round markers in FIG. 3, depicting the maximal peak, showing that different maximal peaks are selected, corresponding to different inferred periods.

Instead, we extend the usage of ACF for extracting multiple periods that comprise the signal. The basis is the observation that different periods have different peak levels in the ACF, while peaks belonging to the same period have roughly the same value. Looking at the bottom plots in FIG. 3 (depicting only a portion of the signal), there is an obvious separation between 3 different levels of peaks (the dashed horizontal lines are merely provided as an illustrative aid); the top ones correspond to the longest period, which is the most perfect, the mid-peaks correspond to a shorter period and the bottom region, that has imperfections due to the nature of the longer periods, belongs to the longer periods. The reason is that the more perfect a period is, the higher the corresponding peaks will be, in all the shifts that match the period.

Consider the following strict definition of a periodic signal with period τ:

∃τ, s.t. ∀t, f(t)=f(t+τ) (8)

which holds when there is a single period and no noise. Whenever multiple periods exist or there is noise in the signal, we may relax three aspects of this definition. First, the equality may be for peaks that belong to the same period. Second, f(t) and f(t+τ) need to be only roughly the same, and not precisely equal. Third, τ, which represents the distance in lags between peaks, does not have to be precise, but can vary (to some extend) between different peaks.

The following is the same algorithm given above slightly simplified and given in pseudocode.

Algorithm 1 Multiple Period Estimation (MPE) algorithm

Input: ACF of a discrete signal xn
Output: A set of (P\hat{ }, ξ) for each inferred period
1: scale ← M AX _SLI C ES
2: periods ← Ø
3: while scale > 0 do
4: Partition the ACF y-axis to scale equal-size slices
5: for slice in slices do
6: Find the ACF peaks within the slice
7: N ← number of peaks within the slice
8: if N ≧ M I N _P EAK S then
9: Compute the gaps between the peaks
10: Compute the gaps PDF with width = 1/fs
11: G ← tallest mode in the gap PDF
12: if probability of G > M I N _P ROB then
13: p ← (G · fs )−1
14: gaps ← number of gaps in G
15: egaps ← min(1, ┌signal_length/pl┐ − 1)
16: ξ* ← gaps/egaps
17: if p ∈/ periods then
18: periods ← periods U (p, ξ)
19: else if previous ξ is smaller than ξ* then
20: replace existing ξ with ξ*
21: if all peaks are in the same slice then
22: break
23: scale ← scale − 1

Alg. 1 lists the pseudo-code of a simplified version of MPE. First, accounting for the separation of periods and relaxing the equality of f(t) and f(t+τ), MPE partitions the ACF peaks into slices (line 4), so that each slice contains peaks belonging to different periods. Since we do not know a priori how to slice the ACF, this is an iterative process, trying a coarser partitioning each time. Accounting for the variations in τ, MPE computes, for each slice that has a sufficient number of peaks, a histogram (PDF) of the intervals (gaps) between peaks (lines 6-10). If there is a significant mode (higher than the given probability MIN_PROB), then it is considered a valid period (lines 12-20). If all signal peaks fall into the same slice, then the algorithm terminates (lines 21-22). Otherwise, it repeats the above process for a coarser partitioning of the peaks. For each inferred period, its confidence, ξ, is calculated by counting the number of gaps that fall into the tallest mode bin, and normalizing it by the number of expected gaps in a perfect signal with the inferred period (lines 13-16). In a perfect signal, all of the peaks that correspond to a given period would fall in the same bin, thus the resulting ξ will be one. When noise or multiple periods exist, the peaks may shift between slices, hence ξ will be lower than 1.

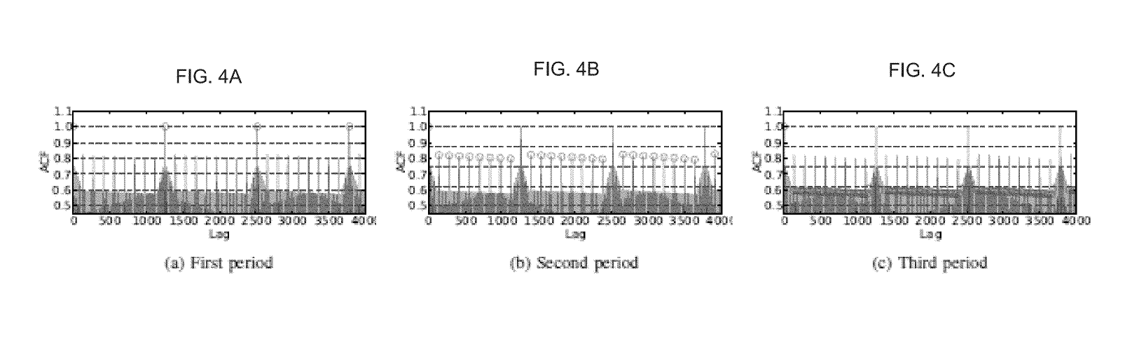

FIG. 4 shows how MPE manages to infer three different periods, by detecting peaks in different slices. Notice that the portioning required for detecting the periods in FIG. 4b and FIG. 4c is coarser than the one used in FIG. 4a, since in the latter, not all the peaks of the second period fell into the same slice. Note that the peak at zero lag which is constant is marked for reference on all figures.

MPE requires setting several parameters that affect its period detection ability and inference error. The resolution of slicing the peaks (MAX_SLICES) is a trade-off between the ability to separate similar periods and the robustness to noise. Fine partitioning has the ability to distinguish periods that are very similar (e.g., a very small imperfection in the shorter period), but makes the noise margins smaller. Meaning, using fine partitioning enables detection of periods with low ratio but is less robust to noise that results in shifting noisy peaks to different slices, thus lowering the accuracy of the period inference or even the ability to infer a period.

The width of the gap PDF bins determines the error that is introduced to the inferred period, and the robustness to noise. Small bins help reduce the error, but when the periods are close to one another, or when facing noise, gaps belonging to the same period may span across multiple bins, hence reduce the probability of detecting the mode that corresponds to the correct period. Additionally, even if the correct mode is detected, the confidence may be small since not enough gaps are contained in the detected mode. When detection of similar periods is required, or the levels of noise is high, the MIN_PROB must be lowered, to enable detection of periods that do not exhibit a clearly dominant gap.

In the algorithm, we use 1/fs, which already encapsulates the error in the inferred period—higher sampling rate, implies lower inference error. Therefore, by using the sampling rate for the bin size we ensure that the period inference error is at most the error introduced by the sampling process. We discuss the remaining parameters in our simulations and evaluation, and their effect on the results, in further sections.

V. Simulation

In this section we evaluate the results of the methods on synthetic signals. We first compare the two methods for signals that are comprised of a single period, and evaluate their performance when facing noise. We then study the ability of MPE to detect multiple periods and explore its operation limits.

A. Simulating Noise

Recall that we consider two types of noise—phase and sampling noise. Simulating phase noise is achieved by varying the exact time of alternations (zero crossings) in xₙ. To this end, we define Pr_{PH} as the probability of a zero-crossing to suffer phase noise and N_{PH} as the number of samples relative to the selected sample, that the zero-crossing should be moved to. Similarly, simulating sampling noise is achieved by selecting random samples with uniform probability Pr_{SM} at which the sampling error is performed, and inverting the value for N_{SM} contiguous samples.

We perform separate simulations for each type of noise, by varying its probability. We set N_{PH} and N_{SM} to use normal distributions, and repeat each simulation 10 times.

B. Single Period Estimation

Denote by P the period we seek to infer, and P̂ the inferred period. We define the accuracy of the inferred period as:

$$Accuracy = 1 - \frac{\vert \hat{P} - P \vert}{max \{ {\hat{P}}_{†} P \}} \qquad ( 9 )$$

An accuracy of 1 indicates that there is no error, and as the error increases the accuracy goes down to zero. This definition aligns with that of the confidence value ξ, where 1 is most confident and the value decays as the confidence is lower. We set the period of the simulated signal to P=100 samples with length of N=1500 samples, i.e., 15 cycles. We first validate that changing the duty-cycle of the signal has no effect on the algorithm results, and find that indeed both DFT and MPE result in no inference error and perfect confidence.

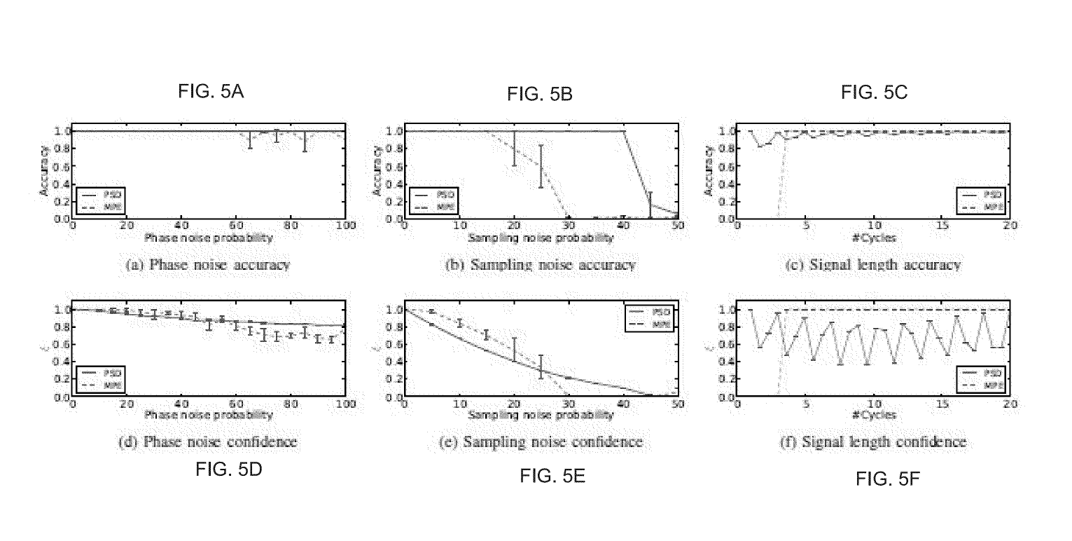

When simulating noise, we use a symmetric duty-cycle (50%) and set N_{PH}NORM(5,1) (up to 20% phase jitter) and N_{SM}NORM(1,0) (at most 1 incorrect sample). FIG. 5 plots the inference error and confidence for varying percentage of phase noise, sampling noise and signal length. The vertical error bars illustrate the variance. FIG. 5a shows that the phase noise has very little affect on the error ratio of both methods, with PSD being completely robust to it. The confidence of both, depicted in FIG. 5d, lowers as the phase noise increases, but remains mostly above 0.5. However, sampling noise has a far greater impact on both methods. FIG. 5b shows that MPE is significantly affected above 20%, exhibiting a large inference error whereas PSD is more robust, starting to exhibit lower accuracy only above 40% of noise. The confidence, shown in FIG. 5e, exhibits low values for both methods, with PSD being below 0.5 from 18% noise, and MPE from roughly 22% noise. The reason that PSD confidence is low is that the phase noise spreads the energy into many different frequencies, hence the overall energy of the harmonics is low. Similarly, MPE suffers from peak gaps falling into different bins in the PDF, thus the number of peaks in the same highest mode becomes lower as the noise increases. However, this can be improved by increasing the bin width, as the result of increased error in the accuracy.

The robustness of the methods to the signal length is shown in FIG. 5c and FIG. 5f. FIG. 5c shows that both methods result in an accurate inference. MPE starts with zero accuracy due to the value of MIN_PEAKS, mandating sufficient periods before detecting a period as valid. PSD exhibits a chainsaw pattern because the computation of the period depends on the signal length. More specifically, it depends on whether the signal length is a complete multiplication of the period. Thus, only when complete multiplications of periods are sampled, the value is perfectly correct.

FIG. 5f shows that MPE results in a perfect confidence, regardless of the length. PSD exhibits significantly taller chainsaw pattern than in the accuracy plot. The reason is that the inferred period is slightly incorrect, making the harmonics not aligned with that period. This results in not accumulating their energy, making the confidence value low. In any case, the value is above 0.3 at all times, thus we use 0.3 as a threshold for the confidence.

C. Multiple Period Estimation

Next, we evaluate the performance of MPE when inferring multiple periods. We construct a signal with 4 periods, which matches a relatively extreme case in our domain—daily, weekly, monthly and yearly periods. Although MPE has no inherent limitation on the number of inferred periods, this helps set efficient parameter values. A dominant gap is selected with MIN_PROB=0.5, which enables sufficient separation and robustness to noise, while extracting periods with clear dominance. The finest slicing resolution is MAX_SLICES=10, since we need to extract at most 4 periods.

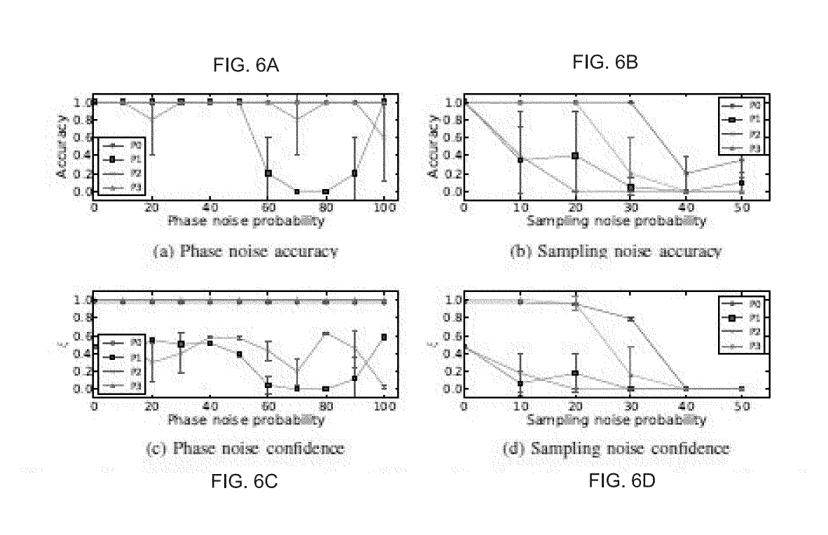

FIG. 6 shows the accuracy and confidence for each resulting period (PO being the shortest and P3 the longest), when facing increasing phase noise and sampling noise. FIG. 6a shows that MPE is robust to phase noise, until reaching 60% phase noise. However, as FIG. 6c shows, the confidence of the two extreme periods (shortest PO and longest P3) is high, while the two middle periods (P1 and P2), have low confidence. Notice however, that even when no noise exists, the confidence is only 0.5. The reason is that P1 and P2 have ACF peaks that reside in several slices, thus even though the accuracy is high, the confidence is relatively low.

FIG. 6b shows that MPE is significantly less robust to sampling noise, especially the two mid-periods, and similar result is witnessed for the confidence value shown in FIG. 6d. Notice that the confidence drops rapidly with the accuracy, making it clear which periods can be trusted and which cannot.

These results indicate that when multiple periods exist, it is essential to maintain a very low sampling error.

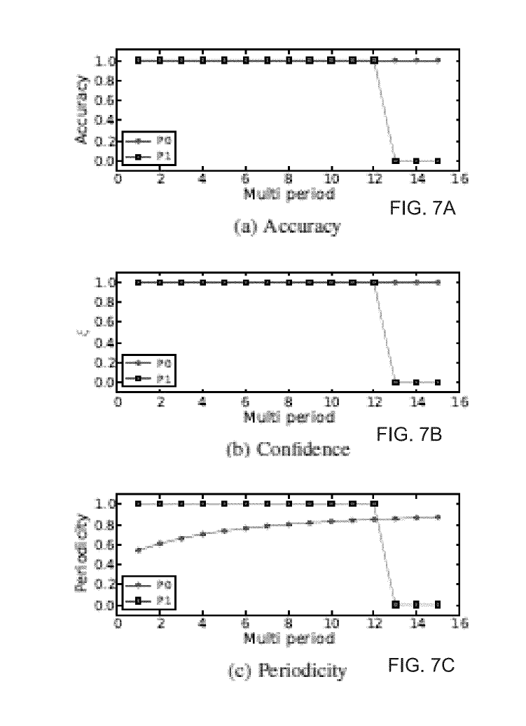

Finally, we measure the effect of the ratio between periods on MPE's results. To this end, we simulate a signal with 2 periods, P0 and P1, and change their ratio by increasing the number of cycles of P0 for each appearance of P1. FIG. 7a and FIG. 7b shows that the two periods are correctly inferred, until reaching 13 cycles of P0, which causes P1 to be completely undetected by MPE (marked as zero in the accuracy and confidence plots).

In order to understand these results, we introduce a Periodicity parameter, which is the average of the peak values which correspond to the selected bin in the gap PDF. Recall that all these peaks come from the same slice. This value captures how perfect the period is, since a high peak value (close to 1) implies almost perfect periodicity in the ACF, while low values indicate that the periodicity is interrupted. FIG. 7c shows that the periodicity of P0 starts with a low value, since for every other cycle, it is interrupted by P1. However, as the ratio between periods increases, the periodicity of P0 increases, i.e., their peak value raises. Once the peak values of P0 reaches 0.8, the peaks shift into the bin of P1, making them look like a single period, thus P1 is not detected as a separate period. Increasing the MAX_SLICES parameter can provide better resolution between the periods but at a cost of a smaller noise margin. For example, running the same analysis with MAX_SLICES=15 will be able to separate the two periods up to 17 cycles of P0 for every P1 cycle.

VI. Evaluation

We evaluate our methods on two real-world Internet processes that capture the dynamics of end-hosts—the availability of end-hosts and the alternation of allocated IP addresses. Understanding these periodic patterns has implications for various network applications, such as malicious host identification, network forensic analysis and other blacklisting based approaches that require tracking infected hosts over time using their IP addresses.

A. Dataset

The dataset for evaluation is obtained from passive sampling of the measuring hosts of DIMES, a community-based Internet measurements system. DIMES utilizes hundreds of software agents installed on user PCs, each having a unique ID, which is associated with the machine it is installed on.

When a machine is online and connected to the Internet, its agent performs a set of measurement scripts and reports the results back to the DIMES central server. These results, along with the mutable IP address of the machine, is reported roughly every 30 to 60 minutes, depending on the time it took the agent to perform the assigned measurements. Notice that this time can vary, either due to special measurement scripts of different sizes, or due to short term network, end-host or server failures.

Using this dataset, we build two datasets for evaluation:

1) Availability. This dataset marks for each agent whether its machine is online or not. Due to the varying samples interval we mark an agent as “offline” only after 3 hours has passed since its last report, and mark the entire interval starting from the last report to the next report as “offline”.

2) Alternation. This dataset marks the IP address that an agent used for reporting measurements, during its “online” time frames (online window). We carefully filter this data to reduce various measurement artifacts. Specifically, if an agent exhibits too many IP alternations in a given online window, or have IP addresses that span multiple ASes, we remove its data, since it is most likely just a measurement artifact. This dataset still exhibits phase-noise as well as sampling noise, the latter being a result of rare measurement artifacts that pass filtering, causing the agent to report a false IP address, e.g., measuring from a location different than the one used for reporting.

B. Results

We ran the PSD and MPE on both datasets. We consider an agent as periodic when it has periods with ξ>0.3, within signals that contain at least 4 cycles.

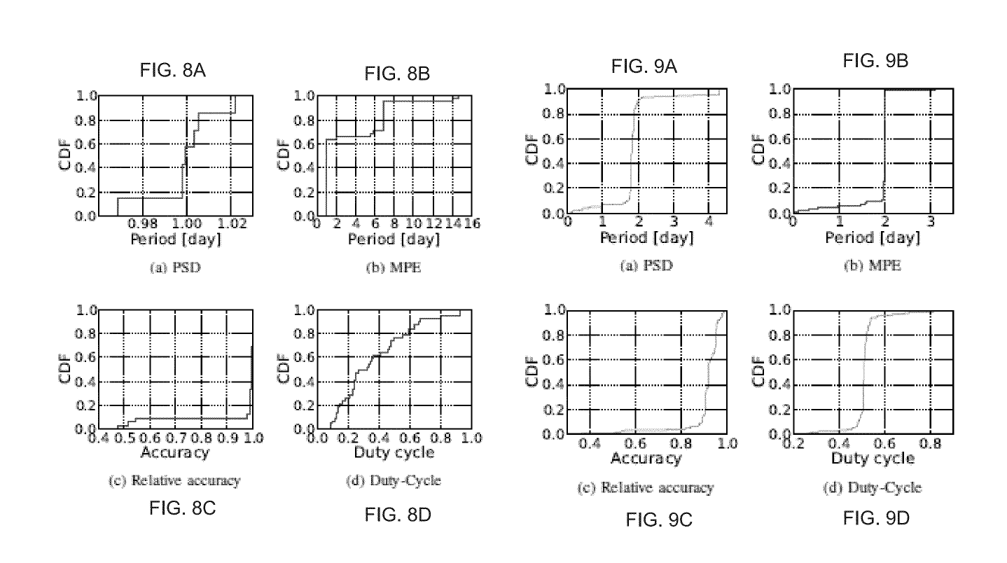

FIG. 8 depicts the results of applying the methods on the availability dataset. Using PSD we found 82 agents that exhibit periodic patterns and using MPE we found 51. FIG. 8a shows that PSD inferred a daily pattern with relatively small error. MPE shown in FIG. 8b managed to detect weekly patterns (7 days) and even a few bi-weekly patterns (14 and 15 days). We note that these weekly and bi-weekly patterns are secondary periods, i.e., each of the agents that exhibited one of them also had a daily pattern. FIG. 8c plots the relative accuracy of PSD and MPE (using Eq. 9), and shows that the two methods agree on over 90% of the periods.

Next, we used a naive method for inferring the duty-cycle, simply counting the amount of online vs. offline time in signals of agents that exhibit periodic patterns. FIG. 8d shows a wide range of duty-cycles, which is the result of capturing different behaviors and the result of our slow detection of offline period. Using the alternations dataset, we found 174 agents that exhibit a periodic pattern using PSD and 131 agents using MPE. FIG. 9 shows that MPE resulted in a perfect 2 days period. PSD resulted in slightly less than 2 days period, thus the relative accuracy in FIG. 9c is mostly above 0.9. The inferred duty-cycle shown in FIG. 9d is 0.5 for almost 90% of the agents, meaning that their IP address is replaced roughly every day, which is a common DHCP default lease time.

Other Applications

The present embodiments can be used for the following tasks:
Studying social behavior for marketing and other applications;
Finding malware activity in the Internet;
Network monitoring; and
Traffic monitoring.

VIII. Conclusion

The present embodiments provide two methods for inferring periodic patterns in data originating from Internet measurements. We first convert the measurement data into a canonical signal, and apply power spectral density analysis for inferring a single dominant period in a fast and efficient way. When more than one period exists, we present a novel Multiple Period Estimation (MPE) technique, based on the time-domain autocorrelation function. Using extensive simulations we show that the methods are robust to phase-noise and sampling noise, and study the capabilities of MPE for distinguishing between periods.

We evaluate the methods on two real-world Internet datasets: availability of end-hosts and IP address alternation. We found periodic patterns in both datasets, the first exhibiting daily, weekly, and even bi-weekly patterns. The latter exhibits daily patterns.

It is expected that during the life of a patent maturing from this application many relevant pulse shaping and symbol decoding technologies will be developed and the scope of the corresponding terms in the present description are intended to include all such new technologies a priori.

The terms “comprises”, “comprising”, “includes”, “including”, “having” and their conjugates mean “including but not limited to”.

The term “consisting of” means “including and limited to”.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. A method for testing a signal comprising:
obtaining the signal;
determining whether the signal has at least one period;
measuring the period; and
outputting the period.

2. The method of claim 1 comprising using power spectral density if only one period is detected, to measure the period, and if multiple periods are detected then obtaining an autocorrelation of the signal, slicing the autocorrelation into slices, for each slice finding peaks and lags, and wherein the measuring the signal comprises setting a current period as a longest one of the lags.

3. The method of claim 2, comprising iteratively coarsening the slices to find further ones of the multiple periods in the signal.

4. The method of claim 2, further comprising stopping the iterative coarsening when all determined periods are contained within a single slice.

5. The method of claim 1, wherein when the determining whether the signal has at least one period comprises determining that the signal has only one period, using a power spectral density to determine the frequency of the only one period.

6. The method of claim 1, wherein the outputting the period comprises outputting a list of all periods found in the obtained signal, and providing a confidence value for each period in the list.

7. The method of claim 6, comprising calculating the confidence value by dividing a number of lags found by a number of lags expected for the current period.

8. The method of claim 1, comprising finding successively longer periods in the obtained signal by iteratively relaxing a time-domain autocorrelation function.

9. The method of claim 8, wherein the finding successively longer periods at least partly comprises finding peak levels in the autocorrelation function, peak levels of different amplitude being assigned to different periods and peak levels of a same amplitude being assigned to a same period.

10. The method of claim 1, wherein the obtaining a signal further comprises shaping the signal to capture a periodic change therein.

11. The method of claim 10, wherein the capturing comprises one member of the group comprising:
a) apply a start value and repeatedly negate the value upon changes in the signal;
b) for a signal having a range, dissecting the range into two range parts and assigning each range part a value from {“1”, “−1”}; and
c) obtaining a number of packets per predetermined time period.

12. The method of claim 1, wherein the output at least one period is used to obtain at least one member of the group consisting of: an availability of end-hosts on a network, a usage of inter-network links on a network for balancing load and cost of transit, optimal peak hour traffic shaping, alternation of allocated IP addresses, malicious host identification, network forensic analysis, and tracking infected hosts over time using their IP addresses.

13. Apparatus for testing a signal comprising:
an input for obtaining the signal;
a period detector for determining whether the signal has at least one period;
a period measurement unit associated with the period detector configured to measure the period; and
an output for outputting the measured period.

14. The apparatus of claim 13 configured to obtain an autocorrelation of the signal, and to slice the autocorrelation into slices, wherein the period detector is configured to determine whether the signal has at least one period by finding for each slice finding peaks and lags, and wherein the period measurement unit is configured to set a period as a longest one of the lags.

15. The apparatus of claim 14, configured to iteratively coarsen the slices to find further periods in the signal.

16. The apparatus of claim 14, configured to stop the iterative coarsening when all determined periods are contained within a single slice.

17. The apparatus of claim 13, wherein period detector detects only one period, the period measurement unit is configured to use a power spectral density to determine the frequency of the only one period.

18. The apparatus of claim 13, wherein the output is configured to provide a list of all periods found in the obtained signal.

19. The apparatus of claim 18, wherein the output unit is further configured to provide a confidence value for each period in the list.

20. The apparatus of claim 19, wherein the measurement unit is configured to calculate the confidence value by dividing a number of lags found by a number of lags expected for the current period.

21. The apparatus of claim 13, configured to find successively longer periods in the obtained signal by iteratively relaxing a time-domain autocorrelation function.

22. The apparatus of claim 21, wherein the finding successively longer periods at least partly comprises finding peak levels in the autocorrelation function, peak levels of different amplitude being assigned to different periods and peak levels of a same amplitude being assigned to a same period.

23. The apparatus of claim 13, wherein the input is configured to shape the signal to capture a periodic change therein.

24. The apparatus of claim 23, wherein the capturing comprises one member of the group comprising:
a) applying a start value and repeatedly negate the value upon changes in the signal;
b) for a signal having a range, dissecting the range into two range parts and assigning each range part a value from {“1”, “−1”}; and
c) obtaining a number of packets per predetermined time period.

25. The apparatus of claim 13, further comprising using the output to obtain at least one member of the group consisting of: an availability of end-hosts on a network, a usage of inter-network links on a network for balancing load and cost of transit, optimal peak hour traffic shaping, alternation of allocated IP addresses, malicious host identification, network forensic analysis, and tracking infected hosts over time using their IP addresses.
